(19) United States
(12) Patent Application Publication
(10) Pub. No.: US 2008/0210929 A1
(43) Pub. Date: Sep. 4, 2008

(54) Organic Thin Film Transistor

(75) Inventors: William F. Hoffman, Palatine, IL (US); Andrew F. Skipor, West Chicago, IL (US)

Correspondence Address: LEVEQUE INTELLECTUAL PROPERTY LAW, P.C., 221 EAST CHURCH ST., FREDERICK, MD, 21701, US

(73) Assignee: Motorola, Inc., Schaumburg, IL (US)

(21) Appl. No.: 11/680,735

(22) Filed: Mar. 1, 2007

(51) Int. Cl. H01L 51/10

(52) U.S. Cl. 257/40; 257/E51.006

(57) ABSTRACT

An organic thin film transistor is formed using an organic semiconducting polymer that contains electrically conductive micro scale or nanoscale metallic plates, particulates, or rods dispersed in the polymer at a concentration less than the percolation threshold to form a semiconducting matrix. The electrically conductive particulates are dispersed to provide a multidimensional micro scale network so that the materials do not provide electrical conductivity between themselves but only between an individual particulate and the organic semiconductor. The transconductance value of the semiconducting matrix is at least one order of magnitude greater than the transconductance value of the neat organic semiconductor, providing a switching speed from an ‘off’ state to an ‘on’ state at least one order of magnitude greater than a switching speed of the neat organic semiconductor.

### FIELD OF THE INVENTION

The present invention relates generally to semiconductor devices having an organic semiconductor element, and more particularly, to organic thin film transistors.

### BACKGROUND

There is a growing research effort in “organic electronics” to replace traditional inorganic silicon and gallium arsenide semiconductors in order to improve the semiconducting, conducting, and light emitting properties of polymers, oligomers, and organic-inorganic composites. Performance improvements, coupled with the ability to process these materials at low temperatures over large areas on materials such as plastic or paper, provide unique opportunities for new applications to address the growing needs of pervasive computing and enhanced mobile connectivity. One of the primary research goals for organic electronics is to manufacture large area inexpensive devices for use in displays, radio frequency identification (RFID) tags, and storage applications. This requires the fabrication of transistors with sufficiently large transconductance and on/off ratios. Towards this end, researchers have been searching for organic semiconductors that show sufficiently high carrier mobility. In organic thin-film transistors (OTFT) extrinsic effects, such as contact resistance, grain boundaries, and interface properties, rather than intrinsic material properties, often limit the mobility. Much of the research on OTFTs focuses on improving performance by increasing the effective mobility. Field effect transistors (FETs) are transistors in which the resistance of the current path from source to drain is modulated by applying a transverse electric field between grid or gate electrodes. The electric field varies the thickness of the depletion layer between the gates, thereby modifying the conductance. Since transconductance decreases linearly with source to drain distance, the thickness of the semiconducting layer has traditionally been minimized to provide the optimum performance. The ultimate figure of merit is the transconductance of the transistor, provided that a sufficiently high on/off ratio and a sufficiently low leakage current can be maintained. Since “plastic” electronics employing inexpensive manufacturing techniques provide inherently lower resolution and much thicker layers than vapor deposited inorganic semiconductor layers, source to drain distances are unlikely to reach into the submicron scale. Current field mobility in organic thin films and restrictions in pattern resolution yield transconductances that are at best marginal for many applications. It has been previously demonstrated that random arrays of nanotubes can form semiconducting and conducting networks, although semiconducting networks suffer degradation during removal of the metallic tubes. However, carbon nanotubes are relatively expensive and difficult to handle. In addition, some of the tubes are conductive and some are semiconductive, which complicates their use to create devices. It would be a significant contribution to the art if a high performance, lower cost OTFT could be developed that did not require such stringent process conditions.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is one example of a field effect transistor in accordance with some embodiments of the invention.

FIG. 2 is a schematic representation of the transconductance effect of a field effect transistor in accordance with some embodiments of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of apparatus components related to organic thin film transistors. Accordingly, the apparatus components and methods have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

It will be appreciated that embodiments of the invention described herein may be comprised of one or more conventional methods or elements. Further, it is expected that one of ordinary skill, notwithstanding possibly significant effort and many design choices motivated by, for example, available time, current technology, and economic considerations, when guided by the concepts and principles disclosed herein will be readily capable of generating such organic thin film transistors with minimal experimentation.

An organic thin film transistor is formed using an organic semiconducting polymer that contains electrically conductive micro scale or nanoscale metallic plates, particulates, or rods dispersed in the polymer at a concentration less than the percolation threshold to form a semiconducting matrix. The electrically conductive particulates are dispersed to provide a multidimensional micro scale network so that the materials do not provide electrical conductivity between themselves but only between an individual particulate and the organic semiconductor. The transconductance value of the semiconducting matrix is at least one order of magnitude greater than the transconductance value of the neat organic semiconductor, providing a switching speed from an ‘off’ state to an ‘on’ state at least one order of magnitude greater than a switching speed of the neat organic semiconductor.

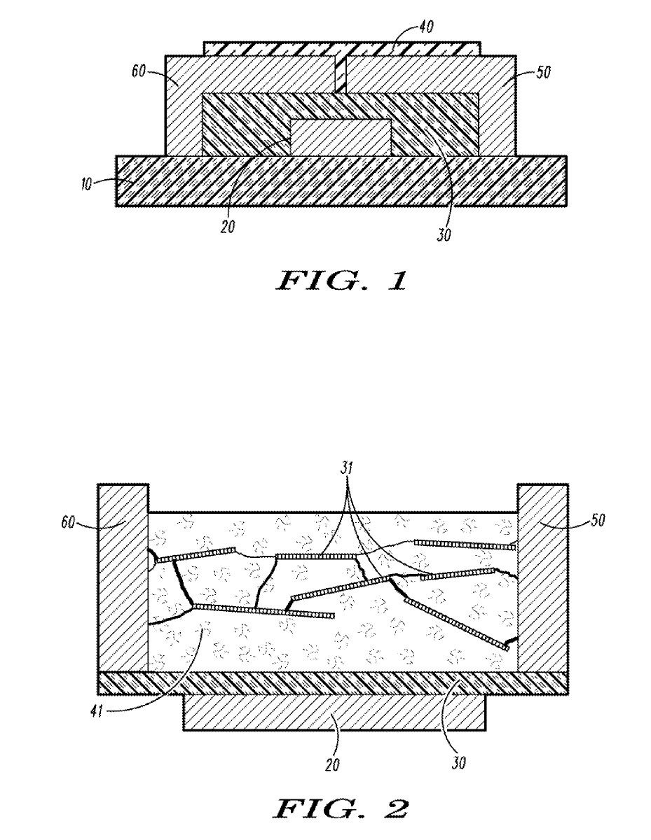

Referring now to FIG. 1, OTFTs utilize an organic semiconductor channel, such as polythiophene, in place of conventional inorganic semiconducting materials. In one configuration of an OTFT, a gate electrode 20 is situated on a substrate 10, a dielectric layer 30 is disposed over the gate electrode 20, an organic semiconductor layer 40 used as an active layer of the transistor contacts the dielectric layer, and source and drain electrodes 50 and 60 also contact the organic semiconductor layer 40. The gate electrode 20 is typically formed in the organic transistor forming region by depositing a gate metal such as Cr/Au or Ti/Au, aluminum, conductive ink or other electrically conducting structure and the thickness of the gate electrode 20 is typically at least 1000 Angstroms. On the gate electrode 20 in the transistor region, a dielectric layer 30 that insulates the gate electrode from other members is made of a non-conducting substance, typically formed by a vacuum evaporation, a printing method a spin coating method or any method of depositing a layer of material with a nominal thickness of 3 micrometers and a conductivity less than 10-14 ohm/cm.

In the printed electronics field the source, gate, and drain are printed using one of several possible methods common to the printing industry including but not limited to offset printing, silk screening or pad printing. The structure of the transistor element can also take on several different structures all of which share a common pattern of having two electrically conducting elements, a source and drain, between which the semiconducting material is printed or deposited and which is in electrical contact with the semiconducting material. A non-conducting layer is deposited or printed between the semiconducting layer and a gate electrode. The order of deposition of these elements varies by application and deposition method and the examples in this document while calling out one or more specific transistor structures do not limit the usefulness of the embodiments to only these transistor structures but to organic thin film transistors in general.

The organic semiconductor layer 40 used as an active layer of the transistor is deposited by a spin coating or other printing techniques on the dielectric layer 30. The thickness of the organic semiconductor layer 40 is less than 5 micrometers. The organic semiconductor layer 40 of the OTFT is a semiconducting material such as, but not limited to, polythiophene, polyacetylene, phthalocyanine, poly(3-hexylthiophene), poly(3-alkylthiophene), α-ω-hexathiophene, pentacene, α-ω-dihexyl-hexathiophene, polythienylenevinylene, bis(dithienothiophene), α-ω-dihexyl-quaterthiophene, dihexyl-anthradithiophene, n-decapentafluoroheptyl-methyl-naphthalene-1,4,5,8-tetracarboxylic diimide, and α-ω-dihexyl-quinquethiophene. In order to enhance the mobility and the driving current of the field effect transistor, an electrically conductive filler is added to the semiconducting material at a low concentration. Some examples of suitable electrically conductive fillers are metallic plates, metallic particulates, metallized polymer particulates, metallized polymer plates, metallized polymer rods, core shell particulates, and nanoscale metal rods. The particulates are micro or nano sized particles that are uniformly dispersed throughout the organic semiconductor layer 40 to provide a multidimensional micro scale network such that the particulates do not provide electrical conductivity between themselves but only between an individual particulate and the organic semiconductor. In order to achieve this, the loading level is kept intentionally low, so as to obviate any bulk conductance from particulate to particulate. This level is generally referred to as the percolation threshold, that is, the concentration of particulates at which the particulates begin to form a connected network. The idea is to make a semiconducting matrix, which is initially insulating, become switchably conductive by adding the smallest possible amount of conductive fillers. Referring now to FIG. 2, the relationship between the electrically conductive particulates 31 and the semiconducting polymer 41 is shown schematically. In this drawing, the dimensions of the electrically conductive particulates 31 is intentionally exaggerated relative to other elements to aid the reader in understanding the embodiments of the present invention. Note that at the desired loading level, below the percolation threshold, the individual electrically conductive particulates 31 do not contact each other, thus a bulk conductivity path is not established through the semiconducting polymer 41. The conduction path between source and drain is instead established by the formation of conducting pathways through the network comprising the conductive particulates and the semiconducting polymer. In the prior art organic semiconductors, the entire conducting link is formed by the semiconducting polymer alone. However, when very slightly loaded with metallized particles, switchable links comprising the highly conducting metallic particulates and the activated semiconducting polymer channel are formed. It is this switchable network that becomes the active component between source and drain as opposed to a homogeneous material. Carriers move from source to drain largely via the highly conducting metallic particulates. Only occasionally and for distances short compared to the source to drain length do they travel through the activated semiconducting polymer, as shown in FIG. 2 by the lines depicting various electrical pathways connecting the particulates 31, generally by the shortest path from particulate to particulate. This represents an effective shortening of the source to drain distance, giving rise to an equivalent increase in the transconductance. As the electrically conductive material 31 concentration increases, the number of switchable current paths increases and the transconductance rises through the exploitation of percolating metallic networks within the semiconducting host. This arrangement can substantially raise the transconductance of a transistor. The goal is to make a semiconducting matrix, which is initially insulating, switchably conductive by adding the smallest possible amount of conductive fillers. Since the electrically conductive particulates are dispersed to provide a multidimensional micro scale network, the particulates do not provide electrical conductivity between themselves but only between an individual particulate and the organic semiconductor. The transconductance value of the resulting semiconducting matrix is at least one order of magnitude greater than the transconductance value of the neat organic semiconductor, providing a switching speed from an ‘off’ state to an ‘on’ state that is at least one order of magnitude greater than the switching speed of the neat organic semiconductor.

It is important to note that when the level of loading of the metallized particulates exceeds the percolation threshold, the filled semiconducting matrix begins to exhibit bulk conductivity, which is undesirable. Beyond the percolation threshold, electrical paths are established that travel completely through the metallized particles that touch each other, from gate to source or drain electrodes. This is undesirable, as the semiconducting matrix can no longer be switched on and off. The actual percolation threshold is different for each combination of organic semiconductor and metallized particulate. For instance, the loading level of metallic plates dispersed in polythiophene to achieve the percolation threshold will be different from, for example, the loading level of metallized polymer particulates dispersed in polyacetylene. In general, we find that the weight fraction of the electrically conductive material is less than three (3) percent relative to the organic semiconductor, with weight fractions between 0.1 and 1 percent being most useful, however, the actual percentage will depend on upon the size and aspect ratio of the metallized particulates, and whether the particulates are rods or plates.

In summary, rather than improving mobility or reducing the feature size of OTFTs, we have exploited the physics of percolation to achieve an effective reduction in channel length, thus increasing transconductance. The carriers flowing from source to drain take advantage of the highly conducting particulates within the semiconducting matrix, flowing partially within the semiconductor and partially through the particulates. Traveling only a fraction of the distance within the semiconductor leads to an effective channel length reduction, and a commensurate increase in transistor performance, enabling relatively inexpensive patterning techniques that can be used for fabrication of low-cost, large-area organic electronics.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

What is claimed is:

1. An organic thin film transistor comprising an organic semiconductor having one or more electrically conductive materials selected from the group consisting of metallic plates, metallic particulates, metallized polymer particulates, metallized polymer plates, metallized polymer rods, core shell particulates, and nanoscale metal rods dispersed therein to form a semiconducting matrix.

2. The organic thin film transistor as described in claim 1, wherein the organic semiconductor comprises one or more semiconducting polymers selected from the group consisting of polythiophene, polyacetylene, phthalocyanine, poly(3-hexylthiophene), poly(3-alkylthiophene), α-ω-hexathiophene, pentacene, α-ω-dihexyl-hexathiophene, polythienylenevinylene, bis(dithienothiophene), α-ω-dihexyl-quaterthiophene, dihexyl-anthradithiophene, n-decapentafluoroheptyl-methyl-naphthalene-1,4,5,8-tetracarboxylic diimide, and α-ω-dihexyl-quinquethiophene.

3. The organic thin film transistor as described in claim 1, wherein the concentration of the electrically conductive material in the organic semiconductor is less than the percolation threshold.

4. The organic thin film transistor as described in claim 1, wherein the one or more electrically conductive materials are dispersed to provide a multidimensional micro scale network such that the materials do not provide electrical conductivity between themselves but only between an individual particulate and the organic semiconductor.

5. The organic thin film transistor as described in claim 1, wherein a transconductance value of the semiconducting matrix is at least one order of magnitude greater than a transconductance value of the neat organic semiconductor.

6. The organic thin film transistor as described in claim 1, wherein a switching speed of the semiconducting matrix from an ‘off’ state to an ‘on’ state is at least one order of magnitude greater than a switching speed of the neat organic semiconductor from an ‘off’ state to an ‘on’ state.

7. The organic thin film transistor as described in claim 1, wherein the weight fraction of the electrically conductive materials is below the percolation threshold.

8. An organic thin film transistor comprising:
an organic semiconducting means selected from the group consisting of polythiophene, polyacetylene, phthalocyanine, poly(3-hexylthiophene), poly(3-alkylthiophene), α-ω-hexathiophene, pentacene, α-ω-dihexyl-hexathiophene, polythienylenevinylene, bis(dithienothiophene), α-ω-dihexyl-quaterthiophene, dihexyl-anthradithiophene, n-decapentafluoroheptyl-methyl-naphthalene-1,4,5,8-tetracarboxylic diimide, and α-ω-dihexyl-quinquethiophene;
electrically conductive means selected from the group consisting of metallic plates, metallic particulates, metallized polymer particulates, metallized polymer plates, metallized polymer rods, core shell particulates, and nanoscale metal rods dispersed in the organic semiconducting means to provide a multidimensional micro scale network such that the materials do not provide electrical conductivity between themselves but only between an individual particulate and the organic semiconducting means to form a semiconducting matrix; and
wherein the concentration of the electrically conductive material in the organic semiconducting means is less than the percolation threshold.

9. The organic thin film transistor as described in claim 8, wherein a switching speed of the semiconducting matrix from an ‘off’ state to an ‘on’ state is at least one order of magnitude greater than a switching speed of the neat organic semiconducting means from an ‘off’ state to an ‘on’ state.

10. The organic thin film transistor as described in claim 8, wherein the weight fraction of the electrically conductive means is below the percolation threshold.

11. An organic thin film transistor having an organic semiconducting element, comprising:
a gate electrode;
source and drain electrodes;
a semiconducting matrix disposed between the gate electrode and the source and drain electrodes, consisting of an organic semiconductor having one or more electrically conductive materials selected from the group consisting of metallic plates, metallic particulates, metallized polymer particulates, metallized polymer plates, metallized polymer rods, core shell particulates, and nanoscale metal rods uniformly distributed therein; and
wherein the concentration of the electrically conductive material in the semiconducting matrix is less than the percolation threshold and sufficient to provide a switching function between the source and drain electrodes.

12. The organic thin film transistor as described in claim 11, wherein the organic semiconductor comprises one or more semiconducting polymers selected from the group consisting of polythiophene, polyacetylene, phthalocyanine, poly(3-hexylthiophene), poly(3-alkylthiophene), α-ω-hexathiophene, pentacene, α-ω-dihexyl-hexathiophene, polythienylenevinylene, bis(dithienothiophene), α-ω-dihexyl-quaterthiophene, dihexyl-anthradithiophene, n-decapentafluoroheptyl-methyl-naphthalene-1,4,5,8-tetracarboxylic diimide, and α-ω-dihexyl-quinquethiophene.

13. The organic thin film transistor as described in claim 11, wherein the one or more electrically conductive materials are dispersed to provide a multidimensional micro scale network such that the materials do not provide electrical conductivity between themselves but only between an individual particulate and the organic semiconductor.

14. The organic thin film transistor as described in claim 11, wherein a transconductance value of the semiconducting matrix is at least one order of magnitude greater than a transconductance value of the neat organic semiconductor.

15. The organic thin film transistor as described in claim 11, wherein a switching speed of the semiconducting matrix from an ‘off’ state to an ‘on’ state is at least one order of magnitude greater than a switching speed of the neat organic semiconductor from an ‘off’ state to an ‘on’ state.

16. The organic thin film transistor as described in claim 11, wherein the weight fraction of the electrically conductive materials is below the percolation threshold.
